(19) United States
(12) Patent Application Publication
(10) Pub. No.: US 2011/0011341 A1
(43) Pub. Date: Jan. 20, 2011

(54) SHOWER PLATE AND PLASMA PROCESSING DEVICE USING THE SAME

(75) Inventor: Shinya Nishimoto, Hyogo (JP)

Correspondence Address: MASUVALLEY & PARTNERS, 8765 AERO DRIVE, SUITE 312, SAN DIEGO, CA, 92123, US

(73) Assignee: Tokyo Electron Limited, Tokyo (JP)

(21) Appl. No.: 12/736,261

(22) PCT Filed: Mar. 6, 2009
(86) PCT No.: PCT/JP2009/054336

§ 371 Date: Sep. 24, 2010

(30) Foreign Application Priority Data
Mar. 24, 2008 (JP) 2008-076429

(51) Int. Cl. C23C 16/455; C23C 16/00

(52) U.S. Cl. 118/723 AN; 239/132.3

(57) ABSTRACT

A shower plate (300) comprises a first flat plate (301), a second flat plate (302) and a third flat plate (303). Flow passages (303a) through which a heat medium flows are formed in the surface of the third flat plate (303) that faces the second flat plate (302). A lattice in which grids cross each other at approximately 90° is formed in the center area of the third flat plate (303), and the flow passages (303a) are bent at approximately 90° that is equal to the angle at which the grids cross each other. By bending the flow passages (303a) in such a manner, a large number of flow passages (303a) can be provided in particularly the center area heated to a high temperature, thereby satisfactorily cooling the shower plate.

This application is a national phase application under 35 U.S.C. §371 of International Application Serial No. PCT/JP2009/054336, filed on Mar. 6, 2009, and claims the priority benefit under 35 U.S.C. §119 of Japanese Patent Application No. 2008-076429, filed on Mar. 24, 2008, which are hereby expressly incorporated by reference in their entirety for all purposes.

### TECHNICAL FIELD

The present invention relates to a shower plate and a plasma processing device using the same.

### BACKGROUND OF ART

Traditionally, to manufacture semiconductor devices and etc., plasma processing devices are used for carrying out microwave plasma CVD (Chemical Vapor Deposition) and etc. for forming thin films. Such plasma processing devices are provided with a chamber, a slot antenna, a dielectric partition wall, a plasma excitation gas supplying section, a mounting table and a shower plate (for example, see Japanese Patent Application Publication No. 2002-299241).

The shower plate transmits plasma generated above the shower plate to below the shower plate, and further feeds process gas directly below the shower plate.

### SUMMARY OF THE INVENTION

### Problems to be Solved by the Invention

By the way, this shower plate becomes hot because of exposure to plasma. Therefore, flow passages are provided in the shower plate for flowing a heat medium for cooling the shower plate. Since the temperature of the shower plate affects the process conducted in the plasma device, satisfactory cooling of the shower plate has been desired.

The present invention was created in light of the circumstances described above, and aims to provide a shower plate containing flow passages to facilitate a satisfactory cooling of the shower plate, and a plasma processing device utilizing the shower plate.

### Means of Solving the Problems

To accomplish the objective, a shower plate of a first aspect of the present invention includes:

a first member;

a second member which is overlapped and joined to the first member; and

a groove formed at a surface of the first member, the surface facing the second member, and the groove functioning as a flow passage in which a heat medium flows by overlapping with the second member,

wherein a sidewall of the flow passage bends in a plane which is parallel to a joint plane of the first member and the second member.

To accomplish the objective, a plasma processing device of a second aspect of the present invention includes the shower plate of the first aspect.

To accomplish the objective, a shower plate of a third aspect of the present invention includes:

a first member;

a second member which is overlapped and joined to the first member;

a groove formed at a surface of the first member, the surface facing the second member, and the groove functioning as a flow passage in which a heat medium flows by overlapping with the second member; and

at least one fin formed in the flow passage.

To accomplish the objective, a plasma processing device of a fourth aspect of the present invention includes the shower plate of the third aspect.

### Effect of the Invention

According to the present invention, it is possible to provide a shower plate containing a flow path for achieving satisfactory cooling of the shower plate and a plasma device using the same.

### BRIEF DESCRIPTION OF THE DRAWINGS

FIG. 1 shows an example of a configuration of a plasma processing device.

FIG. 2 is a plane view showing an example of a radial line slot antenna.

FIG. 3 is a plane view showing an example of a configuration of a shower plate of a first embodiment of the present invention.

FIG. 4 shows a cross sectional view of line IV-IV shown in FIG. 3.

FIG. 5 is a plane view showing a first flat plate of the shower plate

FIG. 6A is a plane view showing a second flat plate of the shower plate.

FIG. 6B is a plane view showing a third flat plate of the shower plate.

FIG. 7 is a plane view showing an example of a configuration of the shower plate of a second embodiment of the present invention.

FIG. 8A shows a partially magnified view of the shower plate in FIG. 7.

FIG. 8B shows a cross sectional view of line VIIIB-VIIIB shown in FIG. 8A.

FIG. 8C shows a cross sectional view of line VIIIC-VIIIC shown in FIG. 8A.

FIG. 9 is a plane view showing an example of a configuration of a shower plate of a third embodiment of the present invention.

FIG. 10A shows a partially magnified view of the shower plate in FIG. 9.

FIG. 10B shows a cross sectional view of line XB-XB shown in FIG. 10A.

FIG. 11 is a plane view showing an example of a configuration of a shower plate of a fourth embodiment of the invention.

FIG. 12A shows a partially magnified view of the shower plate in FIG. 11.

FIG. 12B shows a cross sectional view of line XIIB-XIIB shown in FIG. 12A.

FIG. 13 shows a modification of the invention.

FIG. 14A shows a modification of the invention, and a partially magnified view of the shower plate

FIG. 14B shows a cross sectional view of line XIVB-XIVB shown in FIG. 14A.

FIG. 15A shows a modification of the invention, and a partially magnified view of the shower plate

FIG. 15B shows a cross sectional view of line XVB-XVB shown in FIG. 15A.

FIG. 15C shows a cross sectional view of line XVC-XVC shown in FIG. 15B.

### EXPLANATION OF NUMBERS

100 Plasma processing device

101 Plasma generation chamber (chamber)

101a Plasma excitation space

101b Process space

102 Top plate (dielectric plate)

103 Antenna

103a Waveguide (shield member)

103b Radial line slot antenna (RLSA)

103c Slow-wave plate (dielectric)

104 Waveguide tube

104a Outer waveguide tube

104b Inner waveguide tube

105 Plasma gas supplying section

106 Substrate holding table

300, 400, 500, 600, 700 Shower plate

301, 401, 501, 601, 701 First flat plate

301a, 401a, 501a, 601 Flow passages (for process gas)

301b, 401b, 501b, 601b Vent

302, 402, 502, 602, 702 Second flat plate

303,403,503,603,703 Third flat plate

303a, 403a, 503a, 603a, 603c, 703a Flow passages (for heat medium)

304, 404, 504, 604 Process gas feed passage

305, 405, 505, 605 Process gas inlet

503b, 503c Fin

603b Barrier

### DETAILED DESCRIPTION OF THE INVENTION EMBODIMENTS OF THE INVENTION

Embodiments of shower plates of the present invention and a plasma processing device using the same are explained, using figures. In these embodiments, explanation is offered, using shower plates employed in a microwave plasma CVD device as an example.

### First Embodiment

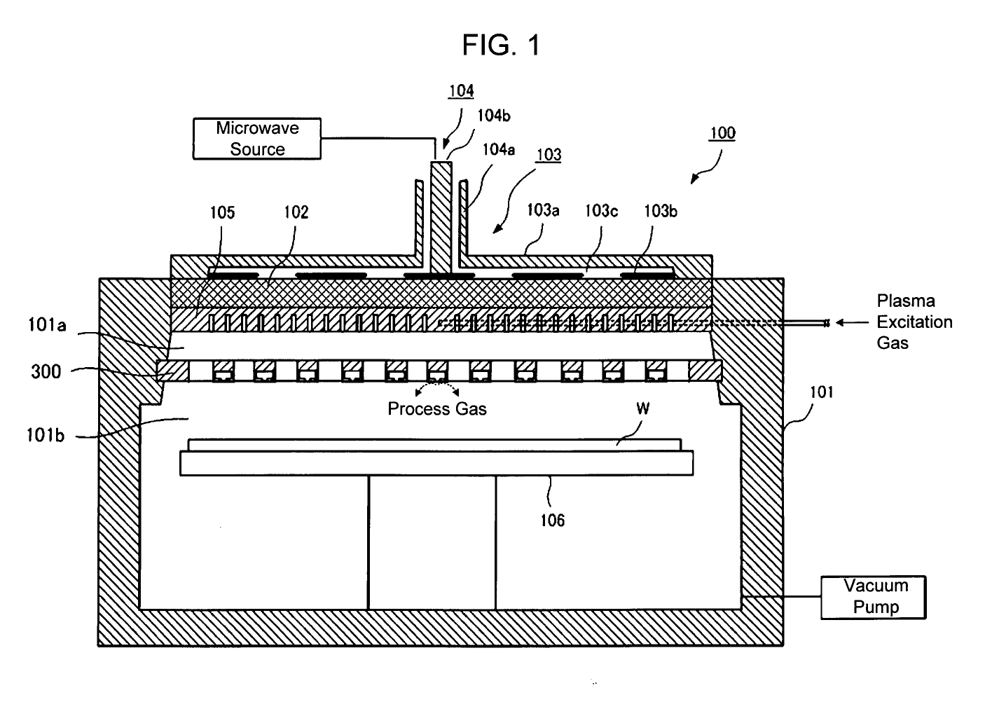

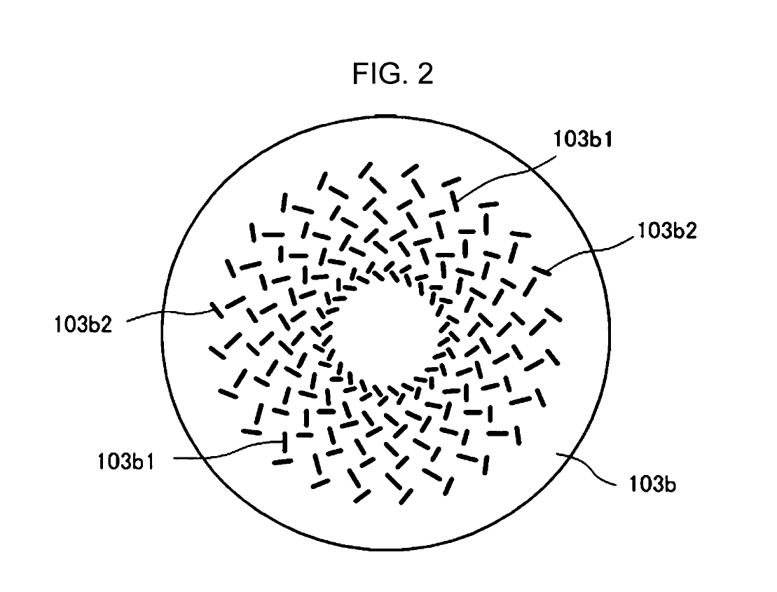

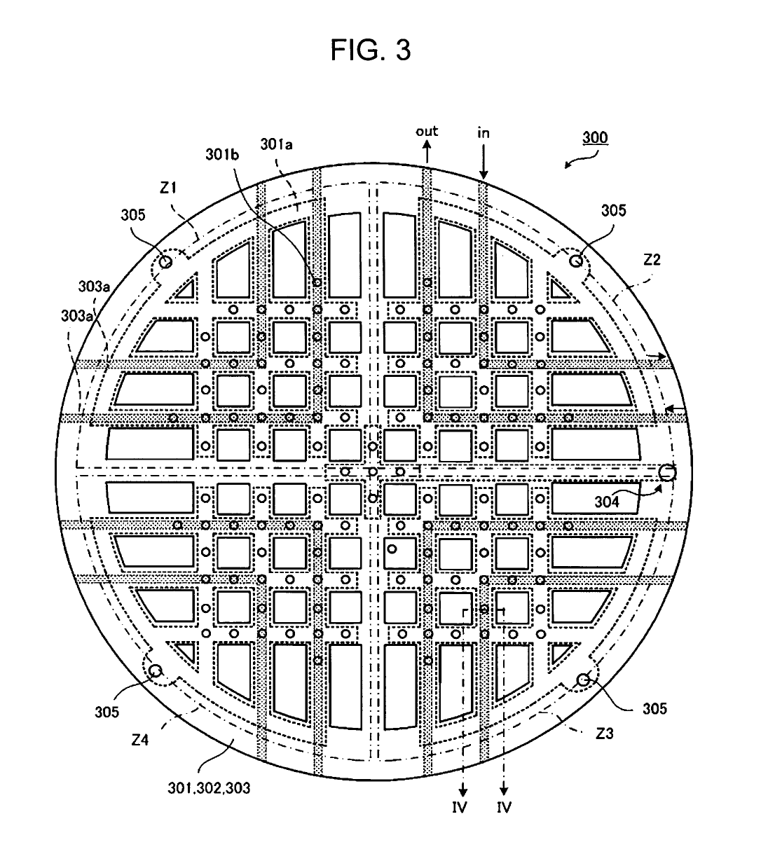

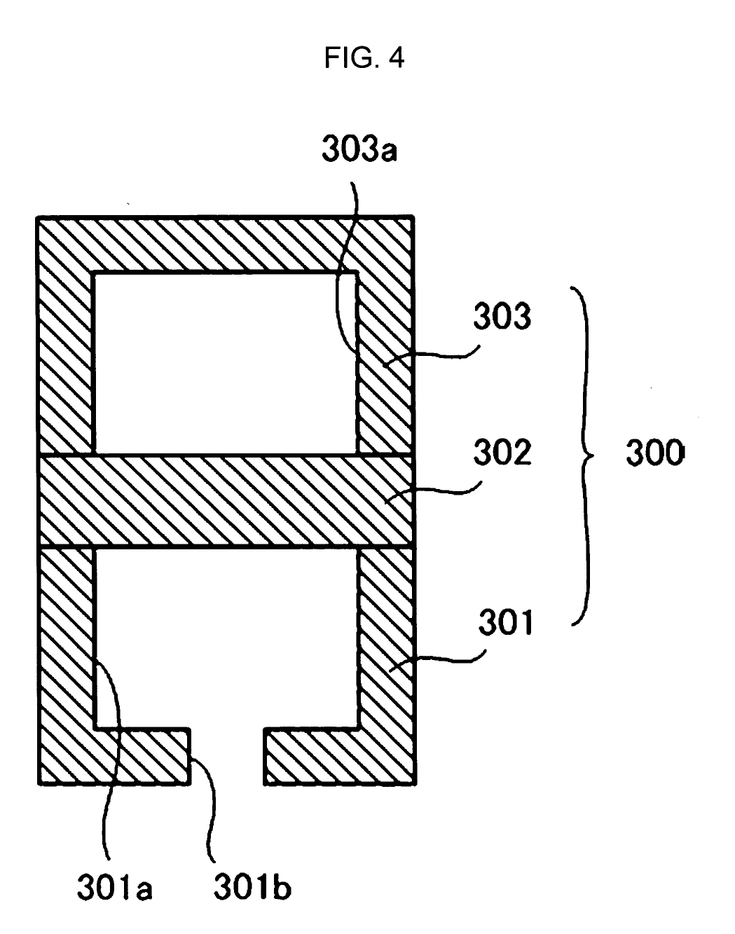

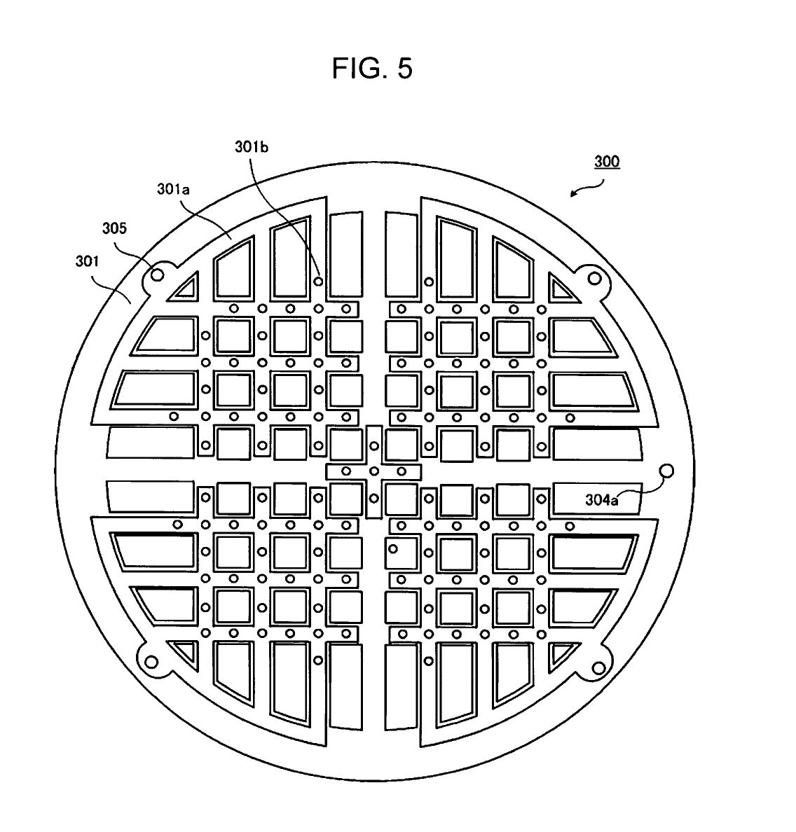

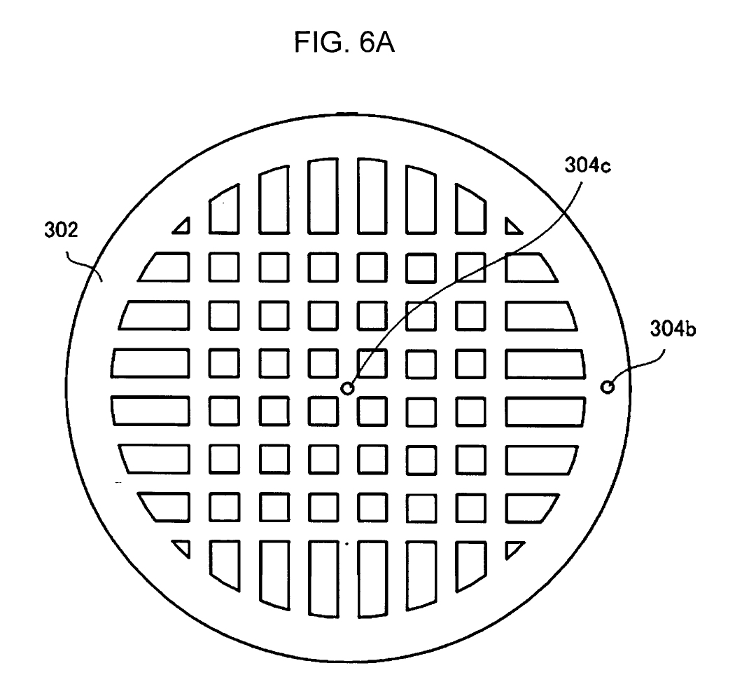

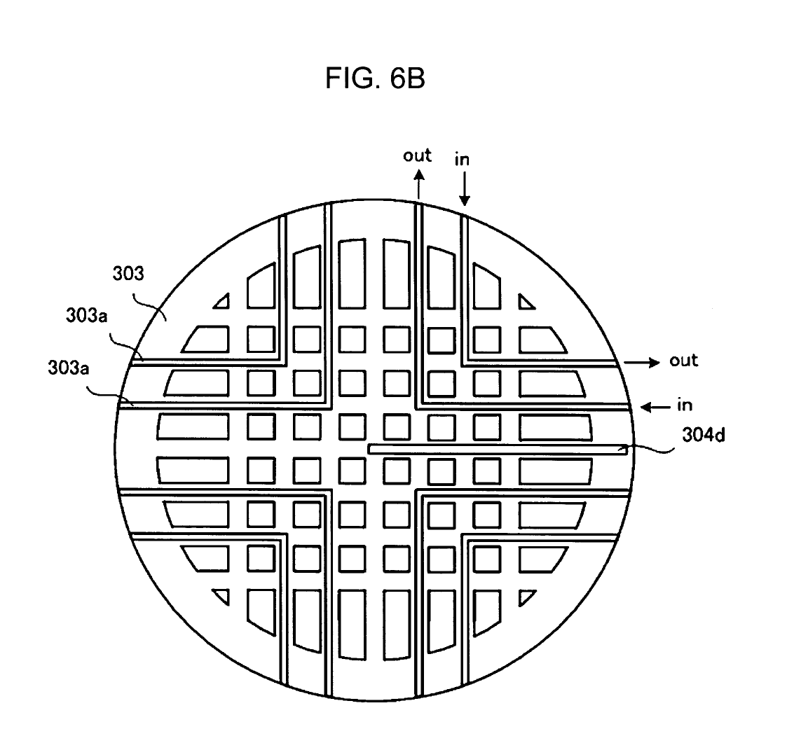

Configuration of a plasma processing device employing a shower plate of a first embodiment of the present invention is shown in FIGS. 1 through 6B. FIG. 1 shows a configuration of a plasma processing device 100. FIG. 2 shows an example of a radial line slot antenna 103b. FIG. 3 is a plane view depicting a shower plate 300 of this first embodiment. FIG. 4 is a diagram showing a IV-IV cross section in FIG. 3. FIGS. 5, 6A and 6B are plane views depicting flat plates that constitute the shower plate 300.

The plasma processing device 100 is composed of a plasma generating chamber (chamber) 101, a top plate (dielectric plate) 102, an antenna 103, a waveguide tube 104, a plasma gas supplying section 105 and a substrate holding table 106. The antenna 103 is composed of a waveguide (shield member) 103a, a radial line slot antenna (RLSA) 103b and a Slow-wave plate (dielectric) 103c. The waveguide tube 104 is a coaxial waveguide tube composed of an outer waveguide tube 104a and an inner waveguide tube 104b.

The plasma generating chamber 101 of the plasma processing device 100 is covered with the top plate 102 made of a dielectric material such as quartz or alumina that transmits microwave. The inside of the plasma generating chamber 101 is maintained in vacuum state by a vacuum pump. The antenna 103 is provided above the top plate 102.

The waveguide tube 104 is connected to the antenna 103. The waveguide 103a of the antenna 103 is connected to the outer waveguide tube 104a of the waveguide tube 104. The radial line slot antenna 103b of the antenna 103 is connected to the inner waveguide tube 104b. The Slow-wave plate 103c is positioned between the waveguide 103a and the radial line slot antenna 103b and constricts wavelength of the microwave. The Slow-wave plate may be constructed from a dielectric material such as quartz, alumina and etc.

Microwave is supplied from a microwave source via the waveguide tube 104. The microwave is transmitted in the radial direction between the waveguide 103a and the radial line slot antenna 103b, and emitted from the slot of the radial line slot antenna 103b.

FIG. 2 is a plane view showing an example of the radial line slot antenna 103b. The radial line slot antenna 103b has a shape so as to cover an opening of the waveguide 103a, and is provided with a plurality of slots 103b1 and 103b2. By providing the radial line slot antenna 103b at the bottom end of the waveguide 103a, it is possible to spread the microwave. As shown in FIG. 2, the slots 103b1 and 103b2 are formed in a form of concentric rings and are mutually perpendicular to each other. The microwave spreads vertically in the longitudinal direction of the slots 103b1 and 103b2, and generates plasma immediately below the top plate 102.

The plasma gas supplying section 105 is provided below the top plate 102. Vents are provided in the plasma gas supplying section 105, and plasma excitation gas is discharged into the plasma excitation space 101a through these vents. Plasma excitation gas containing, for example, argon (Ar), krypton (Kr), xenon (Xe) and etc. is supplied from the plasma gas supplying section 105 to the plasma excitation space 101a, and the plasma gas is excited by microwave to generate plasma.

The shower plate 300 is provided below the plasma excitation space 101a in the chamber 101. The shower plate 300 is made of a metal such as stainless steel, aluminum and etc. As shown in FIG. 3, the shower plate 300 is a flat circular plate, and in its central area, a lattice is provided so that ridged grids intersect at approximately 90°. The plasma generated in the plasma excitation space 101a traverses openings formed by the grids of the lattice, and fed to the process space 101b. As shown in FIG. 3 and FIG. 4, flow passages 301a for supplying process gas and vents 301b are provided in the shower plate 300. The process gas is supplied from a process gas supply source, which is not shown in the figure, via the flow passages 301a and the vents 301b to the process space 101b.

Since the shower plate becomes hot during plasma processing, a plurality of flow passages 303a are provided in the shower plate 300 for passing a heat medium. In this first embodiment, the flow passages 303a are provided by bending at an angle of 90° which is the angle of the intersections of the lattice. Based on this, the shower plate 300 is divided into fan-shaped areas Z1-Z4 with a central angle of 90°, and a heat medium whose temperature has been adjusted for the temperature of each area Z1-Z4 is introduced into the flow passage 303a. With this, it becomes possible to adjust the temperature of the shower plate 300 for each of the areas Z1-Z4. Moreover, as shown in FIG. 3, by passing the heat medium in opposite directions in the two flow passages 303a provided in each area, uneven cooling of the shower plate 300 can be prevented.

When forming an oxide film, a nitride film, or an oxynitride film of silicon on a silicon wafer, O₂, NH₃, N₂, H₂ or etc. is supplied as process gas from the shower plate 300 to the process space 101b. When carrying out an etching process on a silicon wafer or etc., fluorocarbon or etc. is supplied as process gas.

In the first embodiment, the shower plate 300 is constituted with three flat plates, namely, a first plate 301, a second flat plate 302 and a third flat plate 303. The shower plate 300 is formed by thermal-diffusion-welding these flat plates. Concretely, as shown in FIG. 5 through FIG. 6B, the first flat plate 301, the second flat plate 302 and the third flat plate 303 are provided in a grid lattice shape such that ridges in each central area intersect at 90°. All lattices formed in each flat plate are in the same shape, and by overlapping, they function as openings for the plasma passage.

Further, as shown in FIG. 5, on a side of the first flat plate 301 facing the second flat plate 302, the flow passages 301a for process gas are formed so as to correspond to the lattice in the central area. As shown in FIG. 4, the flow passage 301a is provided as a groove having a rectangular cross sectional shape, and it forms a closed space by joining with the second flat plate 302 and functions as a flow passage. In the first embodiment, the flow passages 303a for heat medium are provided with being bent in the middle region (central area) of the shower plate 300, and the temperature control is done by dividing the shower plate into almost four uniform regions Z1-Z4. Corresponding to this, the flow passages 301a for process gas are provided by dividing the shower plate into total five areas in the lattice, four of which correspond to the regions Z1-Z4 and one of which corresponds to the center region of the lattice of the shower plate. By doing this, it becomes possible to control the flow rate and etc. of the process gas individually in each area, and uniform process can be realized. In addition, vents 301b are provided on a bottom side of the flow passages 301a for discharging the process gas. The flow passages 301a and vents 301b are arranged such that the process gas is discharged uniformly onto the wafer W. In this first embodiment, they are uniformly arranged in an area facing the wafer W. To the flow passages 301a other than those in the central area, the process gas is introduced from a process gas supplying source, which is not shown in the diagram, via process gas inlets 305. For the flow passages 301a in the middle region, the process gas is introduced via a process gas feed passage 304. As shown in FIG. 5, FIG. 6A and FIG. 6B, the process gas feed passage 304 is formed from an inlet 304a provided in the first flat plate 301, holes 304b and 304c provided in the second flat plate, and a groove 304d provided in the third flat plate. Gas entering from the inlet 304a of the first flat plate 301 traverses the third flat plate 303, and is discharged from vents in the central area of the first flat plate 301. In this first embodiment, such a configuration is possible since the three flat plates provided with the flow passages and the vents are joined by thermal diffusion welding. The shape and arrangement of the flow passages 301a and vents 301b are not limited to those illustrated, and suitable modifications are possible.

The second flat plate 302 is formed so that the lattice intersects at 90° in the middle region as shown in FIG. 6A. Sides facing the first flat plate 302 and the third flat plate 303 are respectively flat, and by overlapping and joining with the first flat plate 302 and the third flat plate 303, the flow passages for process gas flow and heat medium flow are formed. In addition, the holes 304b and 304c for the process gas feed passage 304 are provided in the second flat plate 302.

The third flat plate 303 is formed such that the lattice intersects at 90° in the middle region (central area) as shown in FIG. 6B. Flow passages 303a bending at 90° are provided on the lattice provided on the third flat plate 303. Side walls of the flow passages 303a are bent on a plane parallel to the joint surface of the third flat plate 303 and the second flat plate 302. By the side walls, grooves are formed in the third flat plate 303, and these grooves constitutes the flow passages 303a. Two flow passages 303a are provided in each region, and in the two flow passages 303a in each region, a heat medium such as a gas, cooled by a cooling device not shown in the figure, flows in opposite directions. In the middle region of the third flat plate 303, a groove 304d for the process gas feed passage 304 is provided.

As evident from FIG. 1, the shower plate 300 is supported by the chamber wall at its periphery. Since the heat in the peripheral region of the shower plate is released via the chamber wall, the middle region of the shower plate tends to become relatively high. In this first embodiment as describe above, the flow passages 303a for heat medium flow are bent at 90° in the middle region of the shower plate, matching with the shape of the lattice. By this, as it becomes possible to gather the flow passages in the middle region of the shower plate that becomes especially hot, the shower plate is cooled satisfactorily compared to the case of forming the flow passage in a linear configuration.

In addition, in this first embodiment, the shower plate 300 is divided into four regions almost uniform from the centre, and it is possible to regulate temperature, flow rate and etc. of the heat medium according to the temperature in each region of the shower plate. By this, a better temperature control is possible based on the temperature of the shower plate. In other words, in this first embodiment, not only is the cooling efficiency in the middle region improved, but the temperature uniformity in the shower plate can also be improved since a better temperature control is possible in response to the temperature in each region of the shower plate.

### Second Embodiment

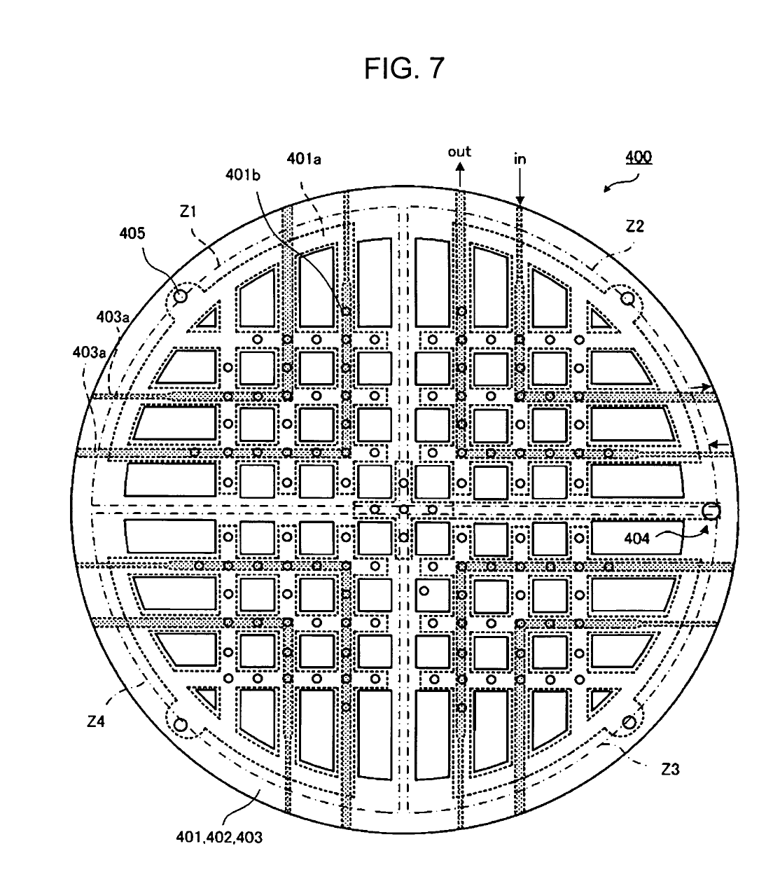

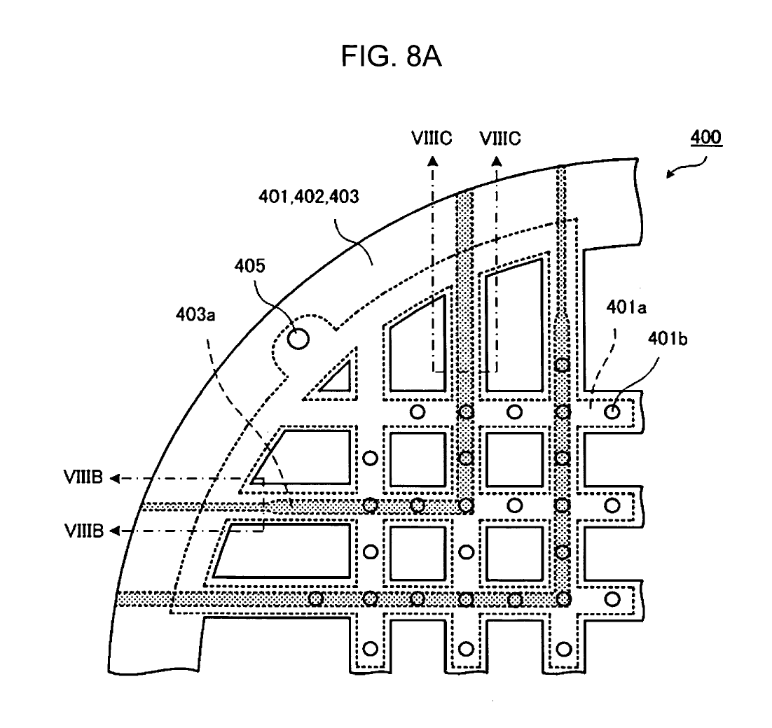

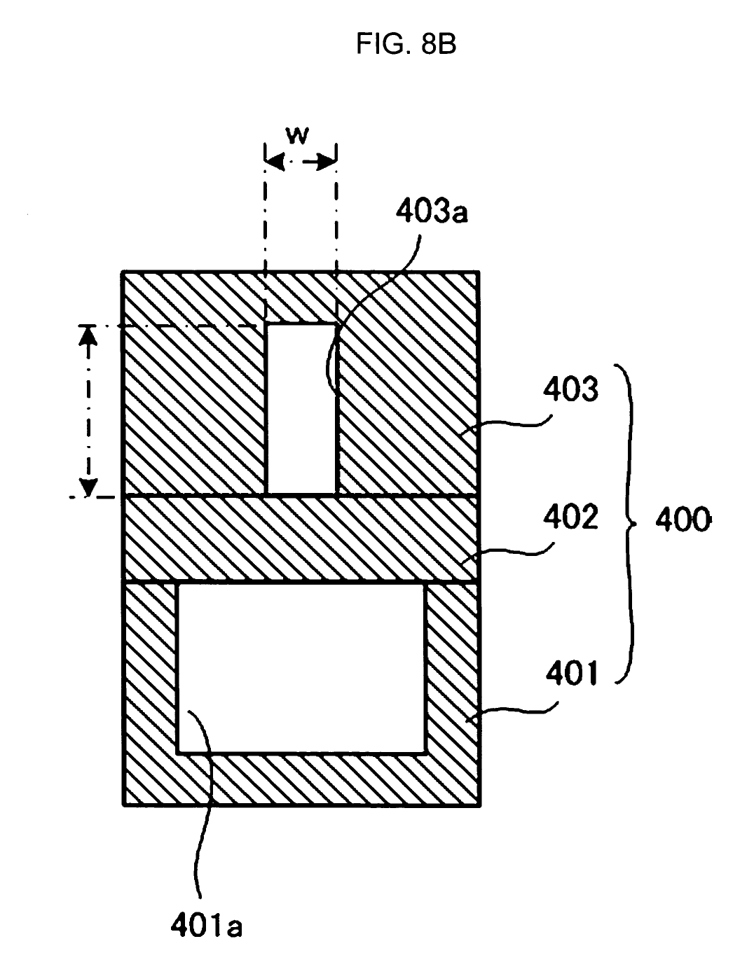

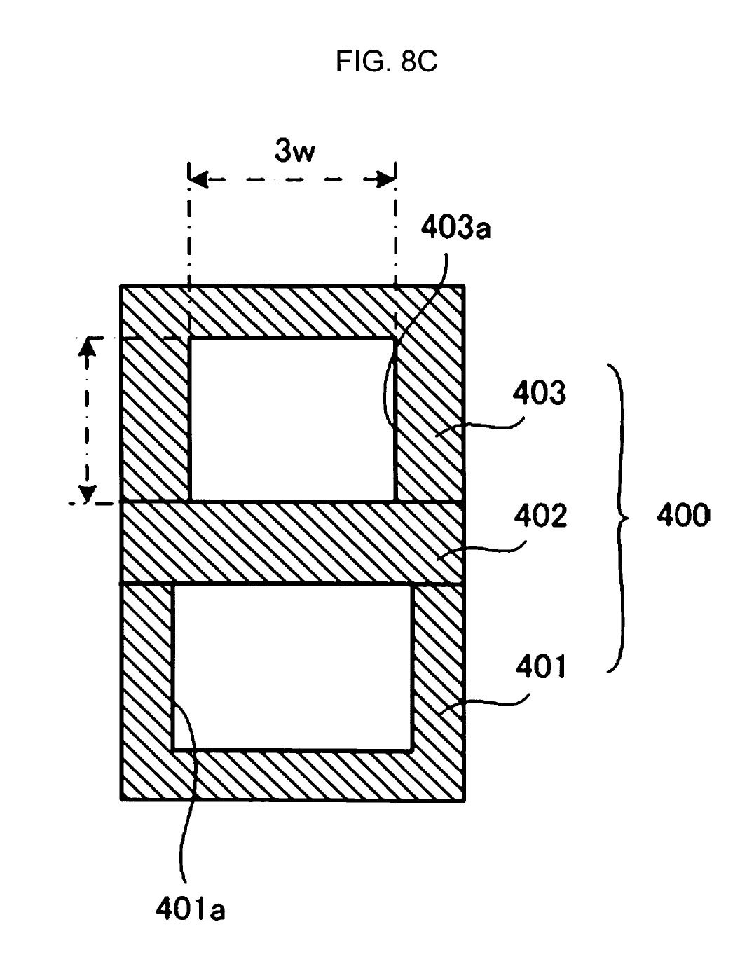

The shower plate 400 of the second embodiment of the present invention is shown in FIG. 7 through FIG. 8C.

The shower plate of this second embodiment differs from the shower plate 300 of the first embodiment with regard to the configuration of the flow passages for the heat medium flow. Detailed descriptions that are common with the shower plate of the first embodiment will be omitted.

Similar to the first embodiment, the shower plate 400 of this second embodiment is composed of a first flat plate 401, a second flat plate 402 and a third flat plate 403. The middle regions of each flat plate are formed as lattices intersecting at 90°. In this second embodiment, the temperature control is also done by dividing the shower plate into four regions Z1-Z4. To achieve the uniform process in the plate, flow passages 401a and vents 401b for process gas supply are provided in each of the four regions Z1-Z4 and in the middle region of the first flat plate 401. Similar to the first embodiment, the process gas is supplied to the flow passages 401a through the process gas feed passage 404 and the process gas inlets 405.

In each region of the third shower plate 403, two flow passages 403a are provided for heat medium. In this second embodiment, the cross sectional area of the flow passage 403a in the vicinity of the inlet of the heat medium is made smaller than the cross sectional area of the flow passage 403a in the area except in the vicinity of the inlet. Due to this, the side wall of the flow passage 403a is bent in a plane parallel to a joint surface of the third shower plate 403 and the second shower plate 402. For example, as shown in FIGS. 8B and 8C, although the depth of the flow passage 403a is same throughout the passage, the width of the flow passage 403a is shaped with a width w near the inlet and with a width 3w in the middle region of the shower plate. The width of the flow passage 403a near the outlet is also same as the width of the middle region.

In the shower plate 400 of this second embodiment, by making smaller the cross sectional area of the flow passage near the inlet of the heat medium, the cooling efficiency is improved, and the temperature in the shower plate can be efficiently controlled to be uniform. As explained above, the temperature in the middle region of the shower plate more easily become high than that of the peripheral region. By narrowing the flow passage of the shower plate near the heat medium inlet, the contact area of the heat medium, which is the heat conduction area, can be reduced. By this, a decrease of the cooling efficiency due to temperature elevation of the heat medium can be avoided before the heat medium, which is introduced into the shower plate, reaches the high temperature middle region.

### Third Embodiment

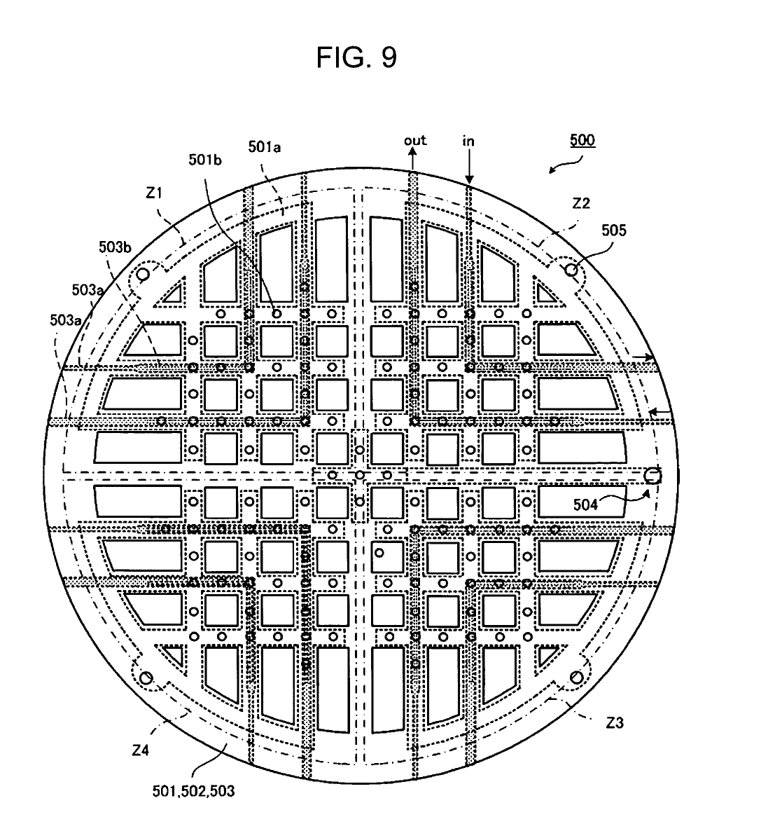

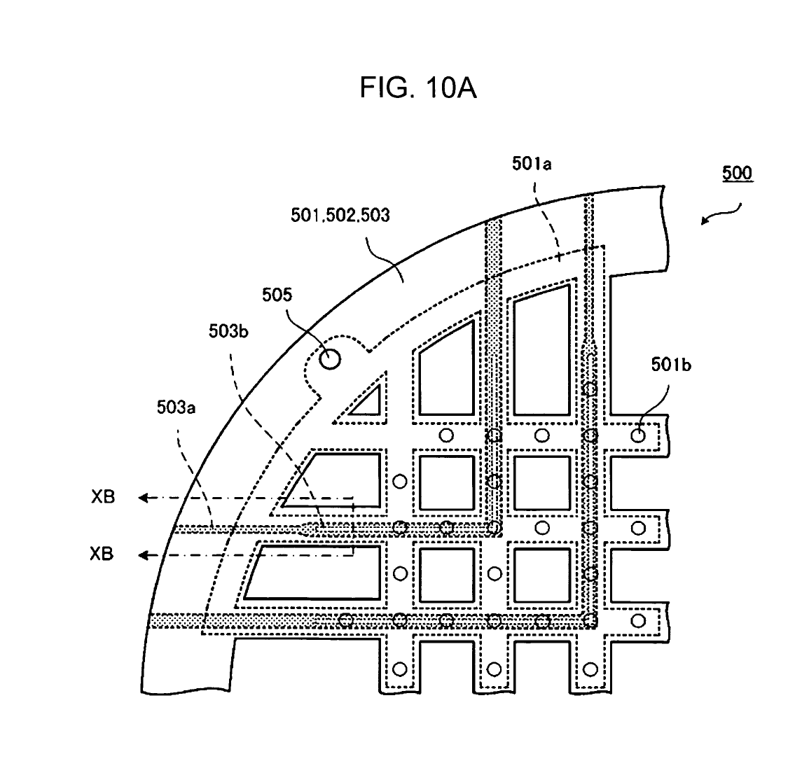

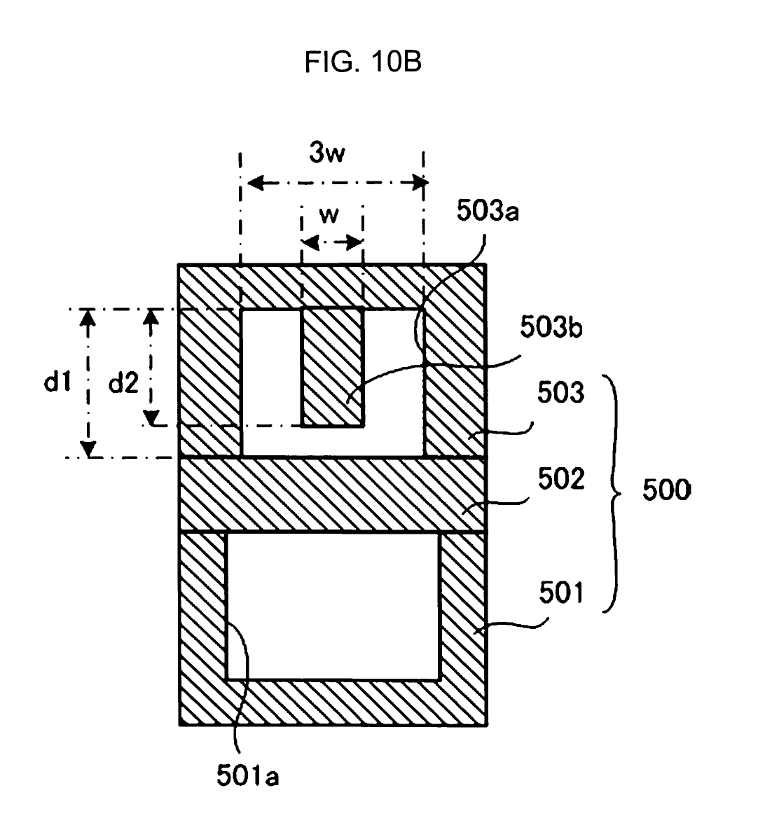

The shower plate of the third embodiment of the present invention is shown in FIG. 9 through FIG. 10B.

The shower plate of this embodiment differs from the shower plate of the second embodiment in that fins are provided in the flow passages of the heat medium. Detailed descriptions that are common with the shower plates of the above embodiments will be omitted.

Similar to the first embodiment, the shower plate 500 of this third embodiment is composed of a first flat plate 501, a second flat plate 502 and a third flat plate 503. The middle regions of each flat plate are formed such that lattices intersect at 90°. Similar to the first embodiment, even in this third embodiment, the temperature control is also performed by dividing the shower plate into four regions Z1-Z4. To achieve the uniform process in the plate, flow passages 501a and vents 501b for supplying process gas are provided in each of the four regions Z1-Z4 and in the middle region of the first flat plate 501. Similar to the second embodiment, the process gas is supplied to the process gas flow passages 501a through the process gas feed passage 504 and the process gas inlets 505.

In each region of the third shower plate 503, two flow passages 503a are provided for heat medium. Similar to the second embodiment, in this third embodiment, the cross sectional area of the flow passage 503a in the vicinity of the inlet of the heat medium is made smaller than the cross sectional area of the flow passage 503a in the area except in the vicinity of the inlet.

In this third embodiment, as shown in FIG. 10B, fins 503b are provided in the flow passages 503a. The fins 503b are integrated into the third flat plate 503. Concretely, in this third embodiment, when the flow passages 503a are formed in the third flat plate 503, the flow passages 503a are formed such that the fins 503b are retained. By joining the third flat plate 503 formed as above with the second flat plate 502 by thermal diffusion welding, the flow passages 503a equipped with the fins 503b are formed. The fin, for example as shown in FIG. 10B, is formed with a width of w, which corresponds to ⅓ of the width 3w of the flow passage 503a. The fin is formed with a height d2, which is smaller than a depth d1 of the flow passage 503a.

By providing the fins in the flow passages as in this third embodiment, the contact area of the heat medium can be increased in the region where the fins are provided. By this, it is possible to increase the cooling efficiency. In addition, in this embodiment, fins are provided only in the middle region of the shower plate. Due to this, it is possible to decrease the contact area of the heat medium in the peripheral region, where the temperature is lower than that in the middle region, compared to the contact area in the middle region. Accordingly, it is possible to further improve the cooling efficiency in the middle region of the shower plate, where the temperature becomes high.

### Fourth Embodiment

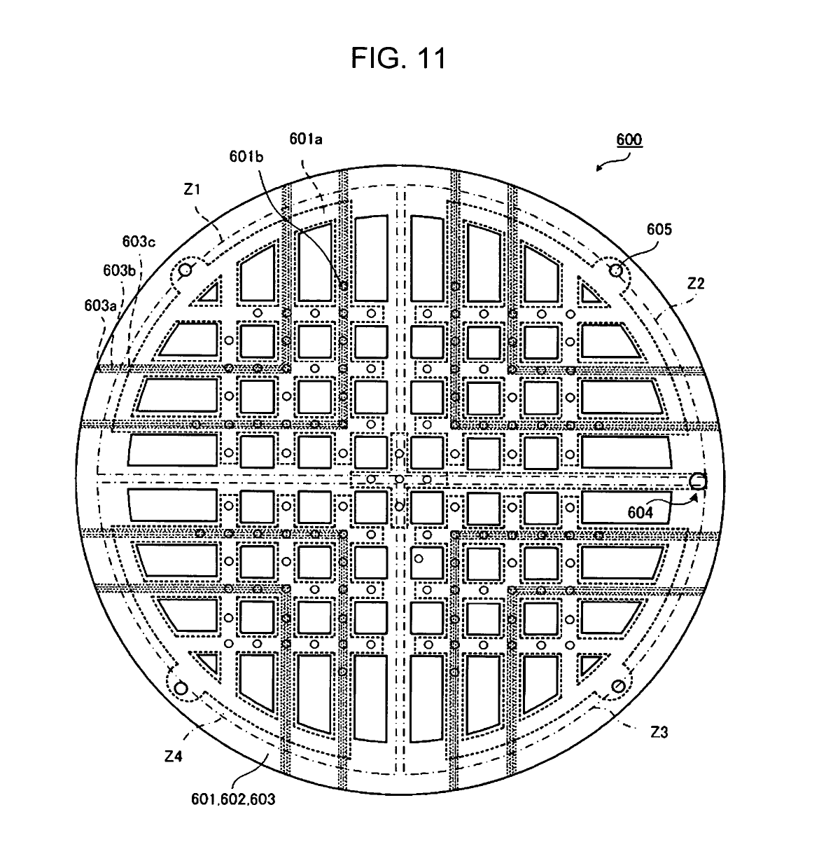

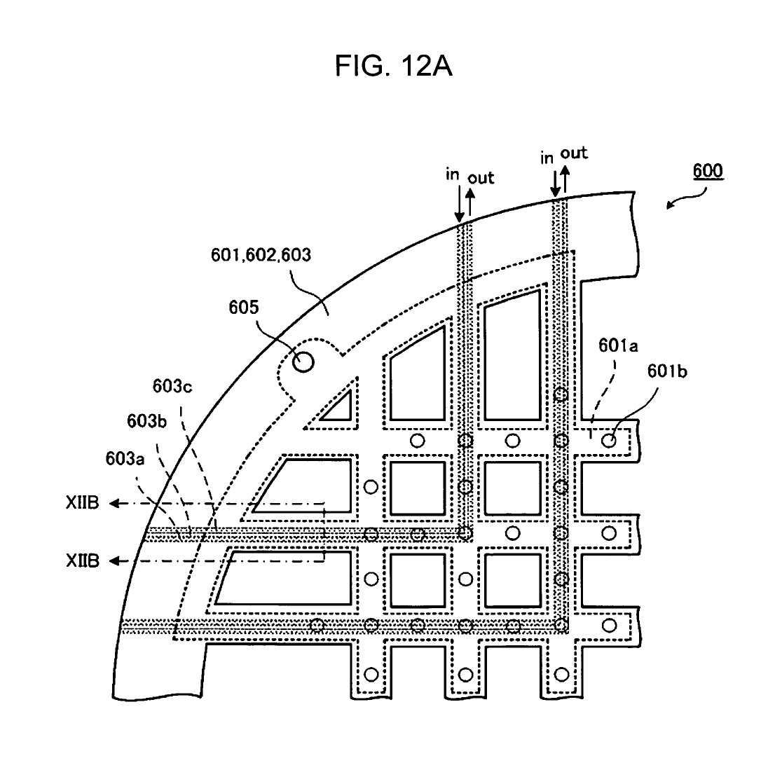

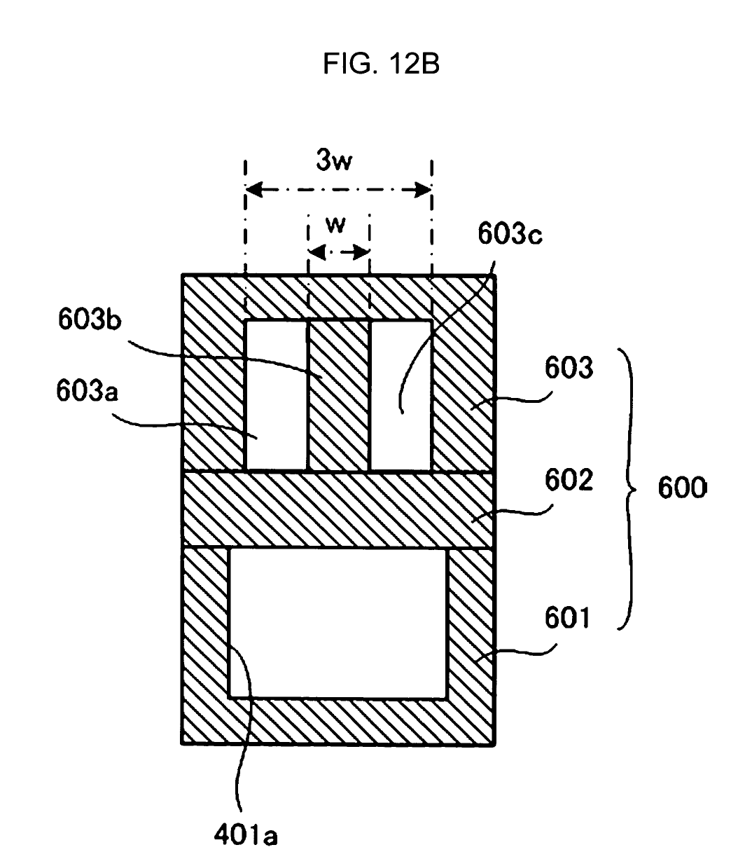

The shower plate 600 of the fourth embodiment of the present invention is shown in FIG. 11 through FIG. 12B. The shower plate of this embodiment differs from the shower plates of each of the above embodiments in that two flow passages are provided in a single lattice for the heat medium flow. Detailed descriptions that are common with the shower plates of other embodiments will be omitted.

Similar to the first embodiment, the shower plate 600 of this fourth embodiment is composed of a first flat plate 601, a second flat plate 602 and a third flat plate 603. The middle regions of each flat plate are formed as lattices intersecting at 90°. Similar to the first embodiment, in this fourth embodiment, the temperature control is also done by dividing the shower plate into four regions Z1-Z4. To achieve uniform process in the plate, flow passages 601a and vents 601b for supplying process gas are provided in each of the four regions Z1-Z4 and in the middle region of the first flat plate 601. Similar to the second embodiment, the process gas is supplied to the flow passages through a process gas feed passage 604 and process gas inlets 605.

In each region of the third shower plate 603, two flow passages 603a and 603c for heat medium are provided in one lattice, and each flow passage is separated by a barrier wall 603b as shown in FIG. 12B. This barrier wall 603b is formed by extending the fin to the same height as the depth of the flow passages 603a and 603c in the entire flow passage. The barrier wall 603b is formed as a single body with the flat plate 603. Concretely, in this fourth embodiment, when the flow passages 603a and 603c are formed in the third flat plate 603, the flow passages 603a and 603c are provided so as to retain the barrier wall 603b. By joining the third flat plate 603 formed as above with the second flat plate 602 by thermal diffusion welding, the flow passages 603a and 603c separated by the barrier wall 603b are formed.

The barrier wall, for example as shown in FIG. 12B, is formed with a width of w, which corresponds to ⅓ of 3w that is the entire width combining those of the flow passages 603a and 603c. It is possible to suitably vary the width of the barrier wall 603b.

By providing the two flow passages for heat medium in a single lattice, it is possible to increase the number of flow passages provided in the shower plate and thus to improve the cooling efficiency.

In addition, in this embodiment as shown in FIG. 11 through FIG. 12B, the heat medium flows in opposite directions in the flow passages 603a and 603c. In this case, a lower-temperature heat medium flows near the inlet of the flow passage 603a while a heat medium heated by the shower plate flows near the outlet of the flow passage 603c, which is close to the inlet of the flow passage 603a. This is also same near the inlet of the flow passage 603c. Due to this, if the flow passages 603a and 603c are viewed as a single entity, it is possible to reduce the uneven temperature distribution in the shower plate compared to the case where the flow passage is single. Particularly when a low-temperature heat medium is feeded, the temperature deviation in the shower plate becomes significant. Accordingly, if it is desired to achieve better cooling with maintaining uniform temperature distribution in the shower plate, it is preferable to introduce a comparatively low-temperature heat medium into flow passages of such configuration.

The present invention is not limited to the embodiments described above, and various modifications and applications are possible. In the embodiments described above, although the explanation was offered with the examples of the configuration of the shower plates assembled from flat members, it is not limited to this, and the members can be curved.

It is possible to suitably combine the various features of the above embodiments. For example, it is possible to provide two flow passages on a single lattice as in the fourth embodiment, to vary the width of these flow passages as in the second embodiment, and to further provide fins in the flow passage as in the third embodiment. In addition, after providing two flow passages on a single lattice as in the fourth embodiment, it is possible to provide a fin in each flow passage.

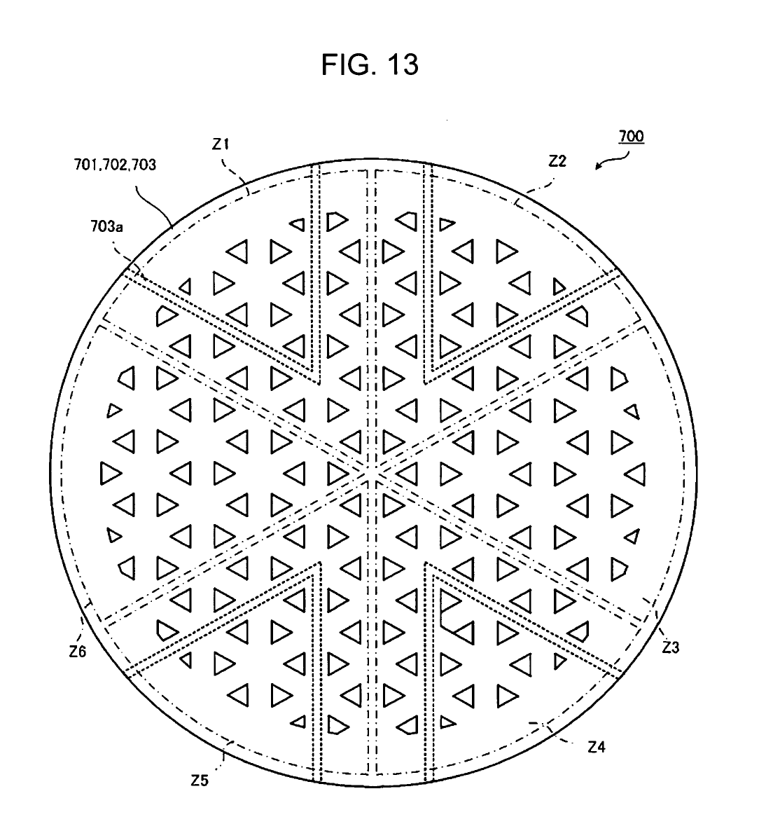

In the embodiments explained above, examples of the shower plates were offered with orthogonally intersecting lattices, but the present invention is not limited to this configuration. For example, as a shower plate 700 shown in FIG. 13, it is possible to change the angle of the lattice formed in the middle region of a first flat plate 701, a second flat plate 702 and a third flat plate 703 to be 60° or etc. In this case, as shown in FIG. 13, by providing the flow passage 703a for heat medium bended at 60°, the shower plate is divided into six zones Z1-Z6. The temperature is controlled in each region individually. The lattices may be provided so as to intersect at an angle less than 60°.

Further, in the second embodiment, though the explanation was offered with the case in which the flow passage is bent similar to that in the first embodiment, it is not limited to this and the flow passage may be provided linearly to laterally cross the shower plate. Moreover, when providing a narrow flow passage near the inlet, it is not limited to the configuration of narrowing the width, and the depth may be made shallow. Also both the width and depth may be varied. Furthermore, in the second embodiment, explanation was offered with the configuration example of varying the width of the flow passage in two stages of width 3w and width w. However, the width of the flow passage may also be varied by dividing into three stages of w, 2w and 3w, and further, may also be varied in multiple stages.

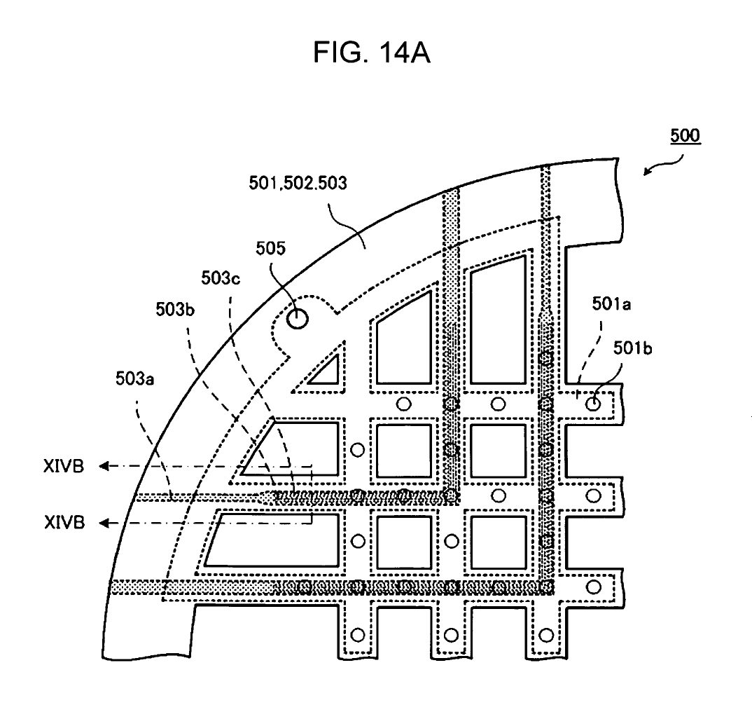

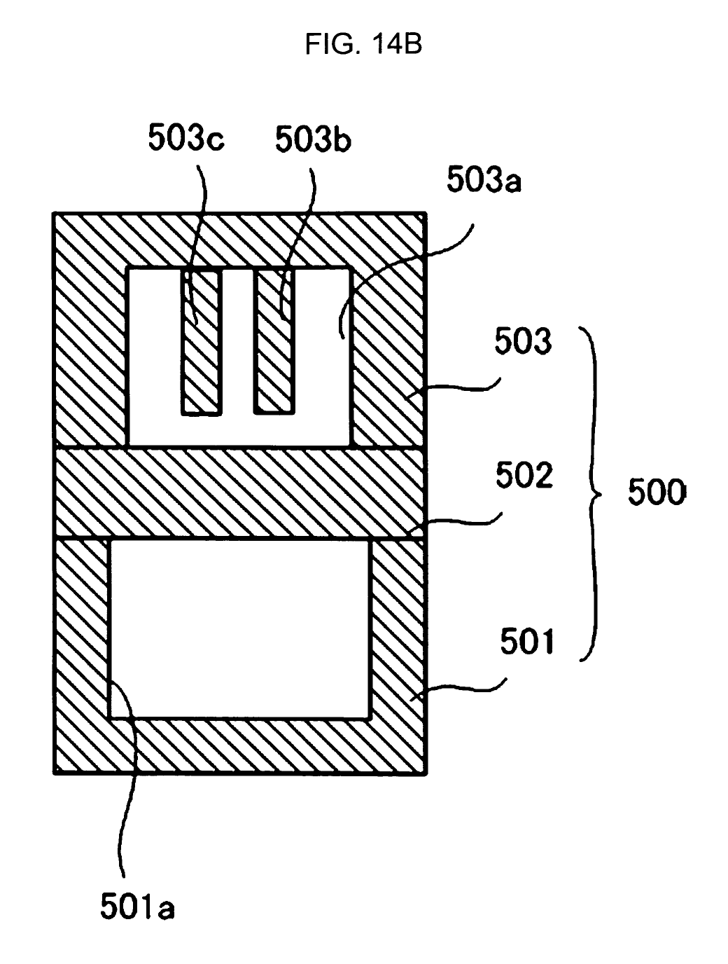

In the third embodiment, though the explanation was offered with the case in which the flow passage is bent similar to that in the first embodiment, it is not limited to this, and the flow passage may also be provided linearly. Further, the numbers of fins, height and etc. are optional. For example, as shown in FIG. 14A and FIG. 14B, two fins 503b and 503c may be provided in the flow passage 503a, and the height of the fins may be made the same as the depth of the flow passage. In addition, the fins are not limited to the configuration of integrating into the third flat plate, and it is possible to provide them in the second flat plate.

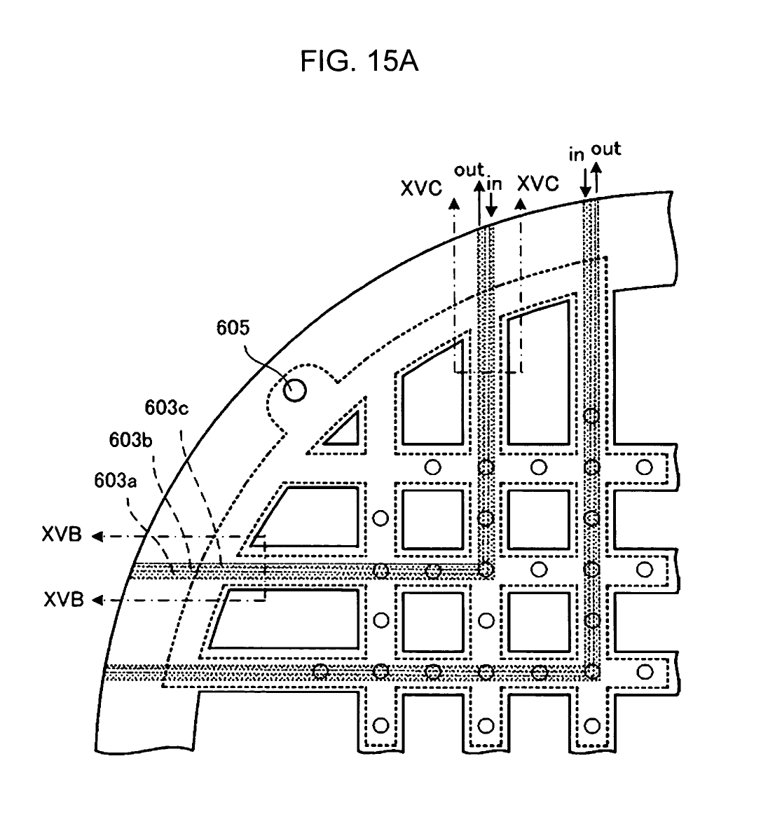

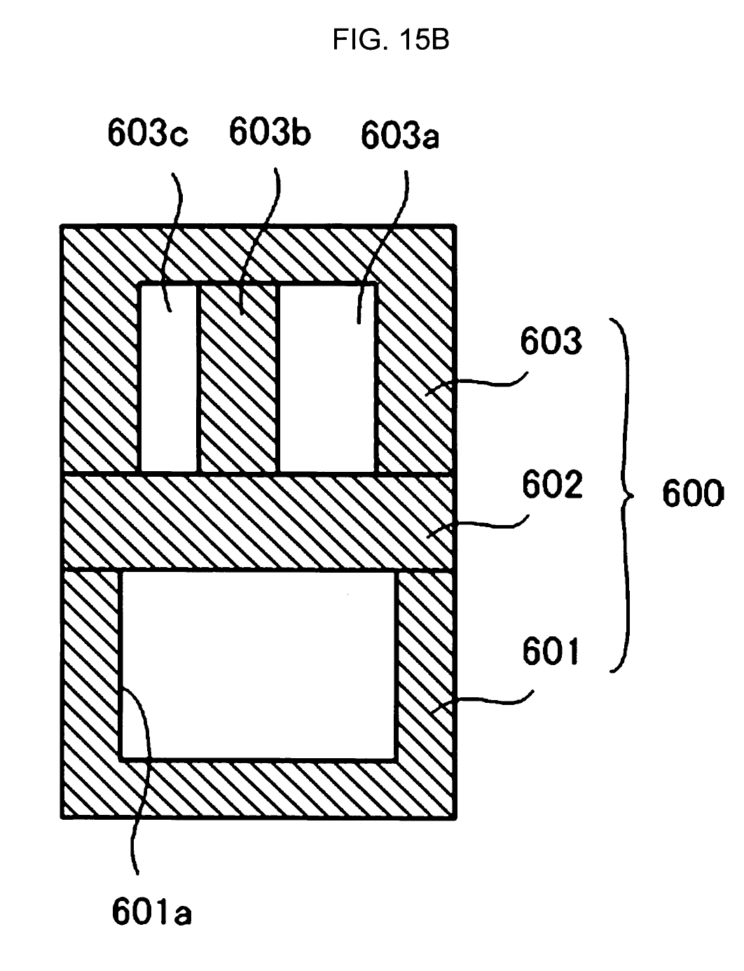

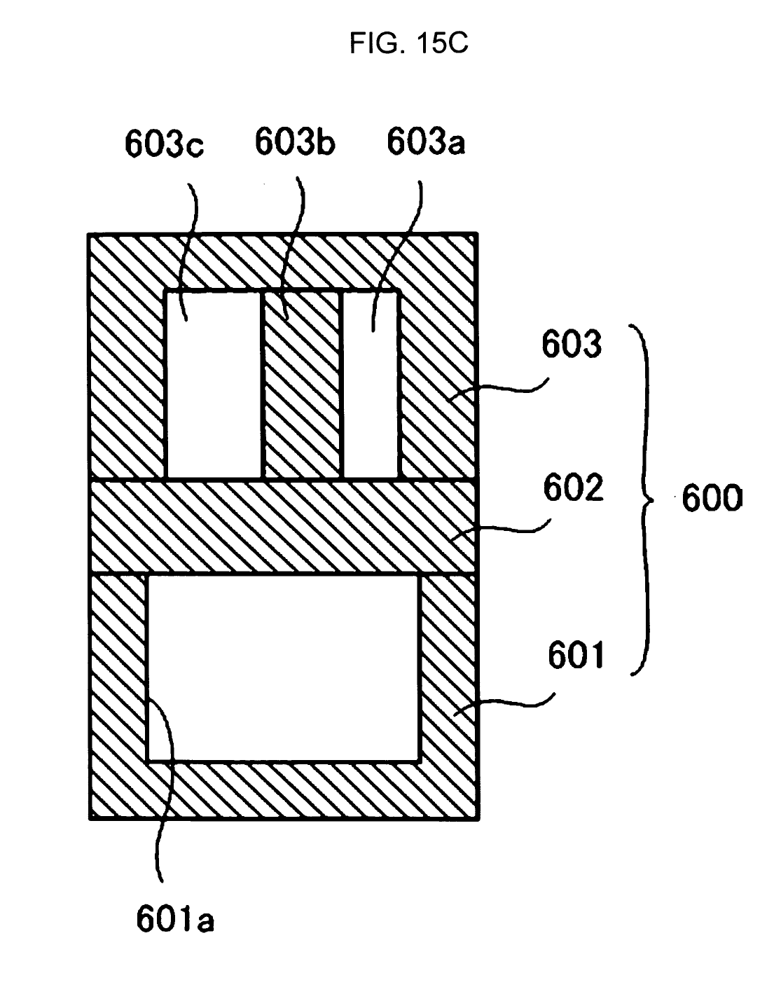

In the fourth embodiment, though the explanation was offered with the case in which the flow passage is bent similar to that in the first embodiment, it is not limited to this, and the flow passage may be provided on a straight line. Further, in the fourth embodiment, although a configuration of the two flow passages in a single lattice was offered, it is not limited to this, and it is possible to provide three or more flow passages. Further, as shown in FIG. 15A, FIG. 15B and 15C, two flow passages provided in the lattice may be formed so that width near the inlet of the heat medium is narrow and width near the outlet is larger. In addition, the barrier wall is not limited to form as a single body in the third flat plate and it may be formed in the second flat plate.

Further, in the flow passages in each embodiment described above, the inner surface of the flow passage that contacts with the heat medium may be roughened to enhance the contact area of the heat medium or to cause a turbulence of the heat medium so as to improve the cooling efficiency.

In all the above embodiments, explanation was offered with the examples of a configuration constituted with three plates. However, it is not limited to this, and it can be two plates or four or more plates. Further, in each of the embodiments described above, explanation was offered with examples, in which the flow passages for process gas are provided in the first flat plate, flow passages for heat medium are provided in the third flat plate, and there are no flow passages provided in the second flat plate. However, it is not limited to this and, for example, it is possible to provide a part of the flow passage for process gas on a side of the second flat plate facing the first flat plate. Similarly, the flow passage for heat medium may be provided on a side of the second flat plate facing the third flat plate. Furthermore, the flow passage for process gas may be provided in the first flat plate, and the flow passage for heat medium may be provided on a side of the second flat plate facing the third flat plate.

In addition, in each embodiment described above, examples were offered with the cases in which each plate was cut into lattice shape, and the shape demarcated by the ridges of the lattice becomes the openings for plasma passage. However, the shape of these openings is not limited to that described in the embodiments described above. The planar shape of the opening is arbitrarily designed, and for example, it is possible to form in a round shape.

In the embodiments described above, a microwave plasma processing device was offered as an example of plasma processing devices. However, it is not limited to this, and it is also possible to use various types of plasma processing devices such as a parallel plate high frequency excitation plasma processing device, an inductively coupled plasma processing device, and etc.

Moreover, in the embodiments described above, although the examples were offered with cases in which a heat medium cooled by a cooling device is used, it is not limited to this, and a heated heat medium may also be used to control the temperature of the shower plate.

The embodiments disclosed herein should be construed as exemplifications in any respect and not as limiting. The scope of the present invention is not indicated by the above descriptions but is indicated by the claims, and it is intended that the scope of the present invention includes all modifications within the scope of the claims and their equivalents.

The present application is based on Japan Patent Application No. 2008-076429 submitted on Mar. 24, 2008. All the specification, claims and drawings of the Japan Patent Application No. 2008-076429 are incorporated in the present specification by reference.

1. A shower plate comprising:
a first member;
a second member which is overlapped and joined to the first member; and
a groove formed at a surface of the first member, the surface facing the second member, and the groove functioning as a flow passage in which a heat medium flows by overlapping with the second member,
wherein a sidewall of the flow passage bends in a plane which is parallel to a joint plane of the first member and the second member.

2. The shower plate according to claim 1, wherein the flow passage is bent and formed in a plane of the member.

3. The shower plate according to claim 1, wherein the flow passages are formed plurally and bent in a central area of the first member.

4. The shower plate according to claim 1, wherein the shower plate is demarcated into a plurality of equal zones by a plurality of the flow passages.

5. The shower plate according to claim 1, the first member comprising a lattice having a line which crosses at a predetermined angle,
wherein the flow passage bends along the line of the lattice at the angle at which the line of the lattice crosses.

6. The shower plate according to claim 1, the flow passage comprising an inlet and an outlet of the heat medium at a peripheral area of the first member or the second member.

7. The shower plate according to claim 1, wherein a cross section of the flow passage in the vicinity of an inlet is formed smaller than a cross section of the flow passage in the other area.

8. The shower plate according to claim 1, comprising at least one fin formed in the flow passage.

9. The shower plate according to claim 8, the first member comprising a lattice having a line which crosses at a predetermined angle,
wherein, by forming the fin over the entire inside of the flow passage, a plurality of the flow passages separated by the fin are formed in one line of the lattice.

10. The shower plate according to claim 1, wherein a surface of the flow passage which contacts the heat medium is roughened so that the heat medium becomes a turbulent flow.

11. The shower plate according to claim 1, wherein the first member and the second member are joined by thermal diffusion welding.

12. The shower plate according to claim 1, further comprising a third member where a flow passage through which a process gas flows is formed.

13. The shower plate according to claim 6, wherein a cross section of the flow passage in the vicinity of the inlet is formed smaller than a cross section of the flow passage in the other area.

14. A plasma processing device comprising the shower plate according to claim 1.

15. A plasma processing device comprising the shower plate according to claim 12.

16. A shower plate comprising:
a first member;
a second member which is overlapped and joined to the first member;
a groove formed at a surface of the first member, the surface facing the second member, and the groove functioning as a flow passage in which a heat medium flows by overlapping with the second member; and
at least one fin formed in the flow passage.

17. The shower plate according to claim 16, the first member comprising a lattice having a line which crosses at a predetermined angle,
wherein, by forming the fin over the entire inside of the flow passage, a plurality of the flow passages separated by the fin are formed in one line of the lattice.

18. A plasma processing device comprising the shower plate according to claim 16.
